(19) United States
(12) Patent Application Publication
(10) Pub. No.: US 2005/0157563 A1
(43) Pub. Date: Jul. 21, 2005

(54) Memory Device and mobile communication device using a specific access procedure

(75) Inventors: Jang-Min Lin, Taipei (TW); Nan-Ray Wu, Hsinchu (TW)

Correspondence Address: QUINTERO LAW OFFICE, 1617 BROADWAY, 3RD FLOOR, SANTA MONICA, CA, 90404, US

(73) Assignee: COMAX SEMICONDUCTOR INC., HSINCHU (TW)

(21) Appl. No.: 10/927,391

(22) Filed: Aug. 26, 2004

(30) Foreign Application Priority Data
Jan. 19, 2004 (TW) TW93101328

(51) Int. Cl. G11C 5/00

(52) U.S. Cl. 365/189.01

(57) ABSTRACT

A memory device for a mobile communication device. The device includes a pseudo static random access memory (PSRAM), a NAND flash memory, an interface controller and a NOR flash memory. When the mobile communication device is powered on, the microprocessor downloads a system program to the PSRAM from the NAND flash memory and shows a startup icon on a display unit according to an initial program, executing the downloaded system program in the PSRAM to accomplish startup of the mobile communication device.

### BACKGROUND OF THE INVENTION

1. Field of the Invention

The present invention relates to memory devices, and more particularly, to a mobile communication device using a memory device and access procedure thereof.

2. Description of the Related Art

As shown in FIG. 1, a conventional mobile phone 10 has a NOR flash memory 12, a random access memory (RAM) 14, a NAND flash memory 16, an interface controller 17 and a microprocessor 18. The NOR flash memory 12 stores system programs, which control the operations and functions of the mobile phone 10. The random access memory 14 provides temporary storage to cooperate with the execution of system programs and application programs. The NAND flash memory 16 stores user data, such as a phone book with names and phone numbers, messages, pictures and downloads.

In FIG. 1, the microprocessor 18 may directly execute the system programs stored in the NOR flash memory 12 during startup when the mobile phone is powered on. Also, the microprocessor 18 can execute multimedia application programs stored in the NOR flash memory 12. However, NOR flash memory is expensive, imposing higher manufacturing cost. Therefore, there is a need for a low cost and large capacity memory device.

### SUMMARY OF THE INVENTION

An object of the present invention is to provide a low cost, large capacity memory device.

According to the above object, the present invention utilizes a NAND flash memory, which replaces a portion of NOR flash memory to store system program codes and user data.

For this object, the present invention provides a memory device in a mobile communication device, includes at least a microprocessor and a display unit. In the memory device, a pseudo static random-access memory (PSRAM) on the first chip is coupled to the microprocessor through a bus, a NAND flash memory is formed on a second chip storing a full or a portion of system program codes controlling functions and operations of the mobile communication device, as well as user data. An interface controller formed on the third chip or on the first chip, coupled to the bus, interfacing to the PSRAM and the NAND flash memory. A NOR flash memory stores an initial program and a startup icon, wherein the microprocessor downloads the system program to the PSRAM from the NAND flash memory and displays the startup icon on the display unit according to the initial program, then executes the downloaded system program in the PSRAM to accomplish startup of the mobile communication device.

According to the above mentioned object, the present invention further provides an access procedure for memory devices in a mobile communication device. The mobile communication device comprises a microprocessor, a display unit, pseudo static random access memory (PSRAM), a NAND flash memory, an interface controller and a NOR flash memory. In the access procedure, a startup icon stored in the NOR flash memory is displayed on the display unit when powering on the mobile communication device. Then, an initial program in the NOR flash memory is executed to download a system program stored in the NAND flash memory into the PSRAM. Next, the downloaded system program in the PSRAM is executed to accomplish startup of the mobile communication device.

### BRIEF DESCRIPTION OF THE DRAWINGS

The present invention can be more understood by the subsequent detail description and examples with reference made to the supplementary drawings, wherein:

FIG. 1 is diagram of a conventional mobile phone;

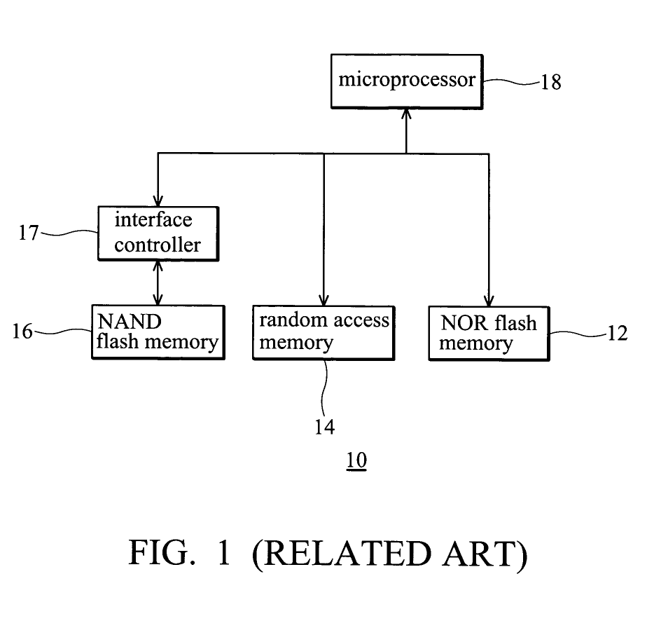

FIG. 2 is a diagram of a mobile communication device according to the present invention;

FIG. 3 is a flowchart of the access procedure of the present invention; and

FIG. 4 is another diagram of the mobile communication device according to the present invention.

### DETAILED DESCRIPTION OF THE INVENTION

The present invention utilizes a NAND flash memory, replacing a portion of NOR flash memory, to store main system program and user data. Furthermore, the present invention provides a NOR flash memory storing an initial program and a startup icon, but not limited to, the memory device utilizing an improved access procedure.

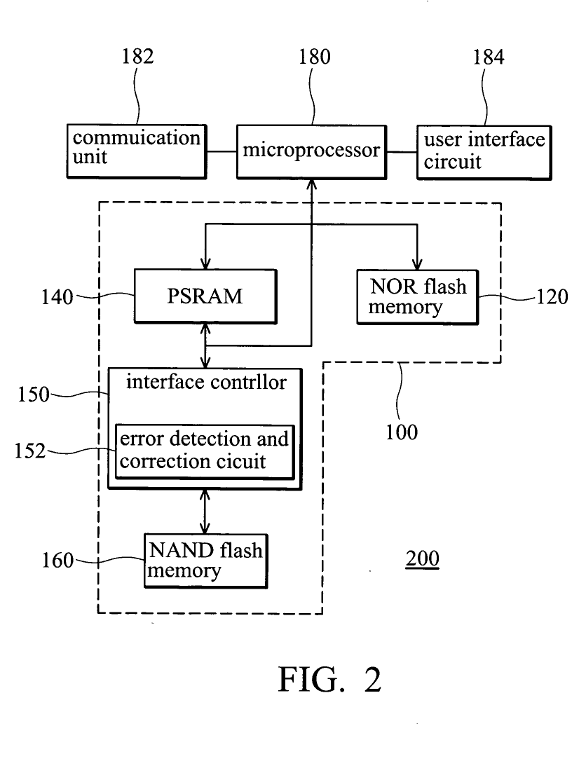

FIG. 2 shows a mobile communication device 200, such as a mobile phone, comprises a memory device 100, a microprocessor 180, a communication unit 182, and a user interface circuit 184. The microprocessor 180 controls operations of the mobile communication device 200, and the communication unit 182, coupled to the microprocessor 180, is used to interface the mobile communication device 200 and a base station (not shown). The user interface circuit 184, coupled to the microprocessor 180, is used to interface users and the mobile communication device 200, by way of a display unit (not shown).

The memory device 100 of the present invention includes a NOR flash memory 120, a pseudo static random access memory (PSRAM) 140, an interface controller 150 and a NAND flash memory 160.

In the present invention, the NOR flash memory 120 is coupled to the microprocessor 180 through a bus, storing a startup icon, an initial program and other programs for startup. For example, the capacity of the NOR flash memory 120 can be less than 16 MB to lower manufacture costs.

The pseudo static random access memory (hereafter referred as PSRAM) 140, is formed on a first chip (not shown) and coupled to the microprocessor 180 through the bus.

The NAND flash memory 160 on a second chip (not shown) stores a system program which controls operations and functions of the mobile communication device 200, user data such as phone books, messages, pictures, music files and the like, and a plurality of multimedia application programs such as MP3 player programs, game programs and the like. In the present invention, capacity of the PSRAM 140 and the NAND flash memory 160 are exceed that of the NOR flash memory 120. For example, the capacity of the PSRAM 140 may over 64 MB, and the capacity of the NAND flash memory 160 may over 128 MB.

Although the present invention utilizes NAND flash memory 160, replacing NOR flash memory, to store system programs and user data of mobile communication device. The NAND flash memory 160, can only be sequentially accessed. Therefore, the interface controller 150 is required such that the data stored in the NAND flash memory can be transferred to PSRAM as a buffer then randomly accessed from PSRAM.

The interface controller 150 is an integrated circuit formed on the first chip, which is coupled to the bus to interface the PSRAM 140 and to connect the NAND flash memory 160. The interface controller 150 also comprises error detection and correction circuits 152 to ensure data integrity between the NAND flash memory 160 and the PSRAM 140, because the NAND flash memory 160 has low data reliability. Additionally, the interface controller 150 has a buffer with capacity less than 4 K bytes inside to temporarily store data. Thus, the interface controller 150 sequentially transfers data from the NAND flash memory 160 to the PSRAM 140.

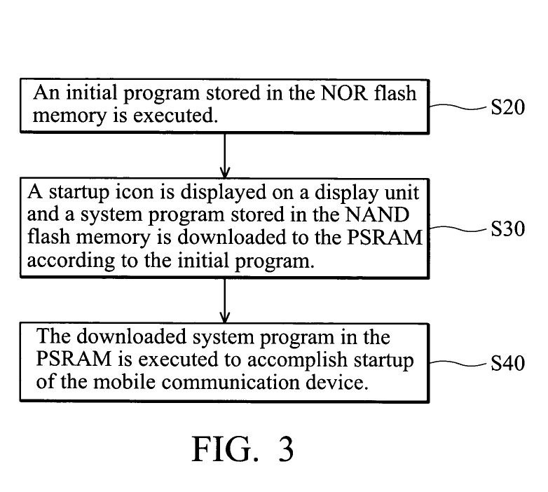

FIG. 3 is a flowchart of the access procedure for memory devices in a mobile communication device according to the present invention. First, in step S20, the microprocessor 180 executes an initial program stored in the NOR flash memory 120 when the mobile communication device 200 is powered on.

In step S30, the microprocessor 180 displays a startup icon on a display unit (not shown) and downloads a system program stored in the NAND flash memory 160 to the PSRAM 140 according to the initial program.

Next, in step S40, microprocessor 180 executes the downloaded system program in the PSRAM 140 to accomplish startup of the mobile communication device 200. In a mobile phone, startup procedure will enable communication with base stations and enter to a standby mode.

The corresponding user data stored in the NAND flash memory 160 can also be downloaded to the PSRAM 140 to cooperate with the system program for startup, in step S40.

Furthermore, the multimedia programs stored in the NAND flash memory 160 can also be downloaded to the PSRAM 140 in step S40 or during interaction with the microprocessor 180. Moreover, when the multimedia programs are executed, corresponding data such as music files, pictures and the like can also be downloaded to the PSRAM 140 for integration into the multimedia programs.

Steps for downloading data or programs stored in the NAND flash memory 160 to the PSRAM 140 are described as follows. First, the interface controller 150 reads out actual data and error detection and correction data from NAND flash memory 160 to the buffer (not shown), according to the instructions from microprocessor 180. Next, the interface controller 150 supplies the actual data in the buffer to the error detection and correction circuits (EDC) 152, which generates error detection and correction data accordingly. The EDC 152 then compares the data and data previously read from the NAND flash memory 160. If no difference is detected, the actual data in the buffer is error-free. If differences are detected, the actual data in the buffer contains at least one error. If no error is detected, the interface controller 150 writes the actual data from the buffer to the PSRAM 140 without any changes. If errors are detected, the interface controller 150 specifies the error bits in accordance with the check result, corrects the actual data in the buffer, and writes the correct data to the PSRAM 140.

Further, data-inputted from Internet or IR transmission device is temporarily stored in the PSRAM 140 and written to the NAND flash memory before powering off. Steps for downloading data or programs stored in the PSRAM 140 to NAND flash memory 160 are described as follows. First, the interface controller 150 compares the actual data from the PSRAM to the buffer thereof, supplies actual data to the error detection and correction circuit 152, which generates error detection data accordingly. The interface controller 150 accesses the error detection and correction data from the buffer and writes the actual data and error detection and correction data to the NAND flash memory 160.

According to the access procedure of the present invention, dependent programs, startup icons and an initial program for startup are all stored in the NOR flash memory. The system program and user data, require larger capacity are stored in the NAND flash memory. Accordingly, the memory device requires only smaller NOR flash memory, no more than 64 Mb, in cooperation with a large-capacity NAND flash memory for multimedia applications.

Further, the PSRAM 140, the interface controller 150 and the error detection and correction circuit 152 can be formed on the same chip by DRAM fabrication processes thereby lowering fabrication cost. They also can be formed in separate chips but assembled in a single package.

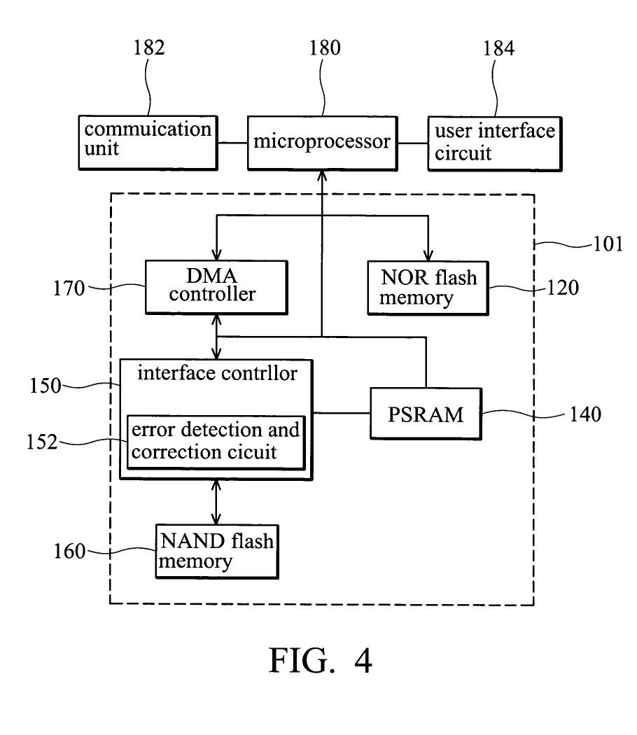

FIG. 4 is another diagram of the memory device 101 of the present invention. The memory device 101 further includes a direct memory access (DMA) controller 170 coupled to the microprocessor 180, the interface controller 150, the NOR flash memory 120, and the PSRAM 140. According to this embodiment, in step S20, the microprocessor 180 executes the initial program stored in the NOR flash memory 120 to output an enable signal to the DMA controller 170. The DMA controller 170 downloads the system-program stored in the NAND flash memory 160 to the PSRAM 140 through the interface controller 150. The microprocessor 180 displays the startup icon on the display unit (not shown), and then in step S40, executes the downloaded system program in the PSRAM 140 to accomplish startup of the mobile communication device 200.

In this embodiment, by way of the DMA controller 170, the microprocessor 180 can still access NOR flash memory 120 when the system program is downloaded from the NAND flash memory 160 to the PSRAM 140. This reduces the time requirement for startup.

While the invention has been described by ways of examples and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A memory device for a mobile communication device, comprising a microprocessor and a display unit, the memory device further comprising:
a pseudo static random access memory (PSRAM) formed on a first chip and coupled to the microprocessor through a bus;
a NAND flash memory on a second chip to store a system program controlling operations of the mobile communication device, and user data;
an interface controller on the first chip and coupled to the bus to interface the PSRAM and the NAND flash memory; and
a NOR flash memory storing an initial program and a startup icon, wherein the microprocessor downloads the system program to the PSRAM from the NAND flash memory and shows the startup icon on the display unit according to the initial program, and executes the downloaded system program in the PSRAM to accomplish startup of the mobile communication device.

2. The memory device as claimed in claim 1, further comprising a direct memory access (DMA) controller coupled to the microprocessor, the interface controller, the NOR flash memory and the PSRAM, wherein the microprocessor outputs an enable signal to the DMA controller, whereby the DMA controller downloads the system program to the PSRAM through the interface controller, and the microprocessor accesses the startup icon from the NOR flash memory for displaying on the display unit, and the microprocessor executes the downloaded system program in the PSRAM to accomplish startup of the mobile communication device.

3. The memory device as claimed in claim 1, wherein the microprocessor stores desired data in PSRAM into the NAND flash memory before powering off the mobile communication device.

4. The memory device as claimed in claim 1, wherein the interface controller comprises an error detection and correction circuit to ensure data integrity between the NAND flash memory and the PSRAM.

5. The memory device as Claimed in claim 3, wherein the capacity of the NOR flash memory is lower than that of NAND flash memory.

6. The memory device as claimed in claim 5, wherein the capacity of the NOR flash memory is no more than 64 Mb.

7. The memory device as claimed in claim 6, wherein the capacity of the NAND flash memory is at least 128 Mb.

8. An access procedure for memory device in a mobile communication device comprising a microprocessor, a display unit, pseudo static random access memory (PSRAM), a NAND flash memory, an interface controller, and a NOR flash memory, the access procedure comprising:
displaying a startup icon stored in the NOR flash memory on the display unit when powering on the mobile communication device;
executing an initial program in the NOR flash memory to download a system program stored in the NAND flash memory to the PSRAM; and
executing the downloaded system program in the PSRAM to accomplish startup of the mobile communication device.

9. The access procedure as claimed in claim 8, further comprising downloading user data stored in the NAND flash memory to the PSRAM for integration into the system program.

10. The access procedure as claimed in claim 8, further comprising writing desired data from the PSRAM into the NAND flash memory before powering off the mobile communication device.

11. The access procedure as claimed in claim 8, wherein the mobile communication device further includes a direct memory access (DMA) controller coupled to the microprocessor, the interface controller, the NOR flash memory and the PSRAM.

12. The access procedure as claimed in claim 11, further comprising output of an enable signal to enable the DMA controller to download the system program stored in the NAND flash-memory to the PSRAM.

13. A mobile communication device, comprising:
a microprocessor;
a communication unit coupled to the microprocessor to interface the microprocessor and a base station;
a user interface circuit coupled to the microprocessor to interface the user and the mobile communication device; and
a memory unit, comprising:
a pseudo static random access memory on a first chip, coupled to the microprocessor through a bus;
a NAND flash memory on a second chip to store a system program for controlling operations of the mobile communication device, and user data;
an interface controller on the first chip and coupled to the microprocessor to interface between the PSRAM and the NAND flash memory;
an error detection and correction circuit on the first chip to ensure data integrity between NAND flash memory and the PSRAM; and
a NOR flash memory coupled to the microprocessor through a bus to store an initial program and a startup icon;
wherein, according to the initial program, the microprocessor downloads the system program from the NAND flash memory to the PSRAM and displays the startup icon on the display unit, the microprocessor executes the downloaded system program in the PSRAM to accomplish startup of the mobile communication device, and the microprocessor writes the desired data from the PSRAM to the NAND flash memory before powering off the mobile communication device.

14. The mobile communication device as claimed in claim 11, wherein the capacity of the NOR flash memory is lower than that of NAND flash memory.

15. The mobile communication device as claimed in claim 11, wherein the capacity of the NOR flash memory is no more than 64 Mb.

16. The mobile communication device as claimed in claim 11, wherein the capacity of the NAND flash memory is at least 128 Mb.

17. The mobile communication device as claimed in claim 14, further comprising a direct memory access (DMA) controller coupled to the microprocessor, the interface controller, the NOR flash memory and the PSRAM, wherein the microprocessor outputs an enable signal to the DMA controller, whereby the DMA controller downloads the system program to the PSRAM through the interface controller, and the microprocessor accesses the startup icon from the NOR flash memory for displaying on the display unit, and the microprocessor executes the downloaded system program in the PSRAM to accomplish startup of the mobile communication device.
